(19) United States
(12) Patent Application Publication
(10) Pub. No.: US 2024/0275122 A1
(43) Pub. Date: Aug. 15, 2024

(54) SYSTEM AND METHOD PROVIDING QUANTUM AND CLASSICAL CORRELATION BETWEEN MULTIPLE LASERS MEDIATED BY A NONLINEAR OPTICAL RESONATOR

(71) Applicant: OEWAVES, INC., Pasadena, CA (US)

(72) Inventors: Lute MALEKI, Pasadena, CA (US); Andrey B. Matsko, Arcadia, CA (US)

(21) Appl. No.: 18/433,174

(22) Filed: Feb. 5, 2024

Related U.S. Application Data
(60) Provisional application No. 63/484,414, filed on Feb. 10, 2023.

(51) Int. Cl. H01S 5/00; H01S 5/40

(52) U.S. Cl. CPC H01S 5/0092; H01S 5/4006

(57) ABSTRACT

A photonic system includes an optical cavity with nonlinear optical characteristics and two or more lasers configured to inject coherent light into the cavity at different frequencies to be locked to the corresponding cavity modes. The cavity, the lasers, and the lock mechanism are configured to correlate the optical properties of the coherent light, wherein the correlation is a classical correlation and/or quantum correlation. Thus, in the photonic system, quantum fluctuations of the two or more lasers can be correlated. The correlation results from the generation of an optical frequency harmonics coincident with the frequencies of the lasers along with simultaneous optical coupling of the lasers and corresponding comb harmonics. As a result of the coupling, the quantum noise of the lasers is correlated so that the frequency noise of the individual lasers can be below the fundamental Schawlow-Townes limit. Method and apparatus examples are described.

### PRIORITY CLAIM AND CROSS-REFERENCE TO RELATED APPLICATION

This patent document claims the priority of U.S. Provisional Application No. 63/484,414, entitled “SYSTEM AND METHOD PROVIDING QUANTUM AND CLASSICAL CORRELATION BETWEEN MULTIPLE LASERS MEDIATED BY A NONLINEAR OPTICAL RESONATOR,” filed on Feb. 10, 2023, the entire disclosure of which is incorporated by reference herein.

### FIELD OF THE DISCLOSURE

Various aspects of the disclosure relate generally to photonic systems and, in particular, to photonic systems with nonlinear optical cavity resonators.

### BACKGROUND

Generation of photon pairs in non-classical states is typically achieved through interaction of light and matter, mediated by nonlinear processes of spontaneous parametric downconversion (SPDC) with a material that has the so called “Chi 2” nonlinearity, and spontaneous four-wave mixing (SFWM) with a material possessing “Chi 3” nonlinearities. These nonlinear processes are also used for generation of squeezed light, but are fundamentally inefficient even with material exhibiting high nonlinearity, so the probability of photon pair generation is strongly dependent on the intensity of light interacting with matter possessing the desired nonlinear properties. To address this limitation, a means for improving the efficiency of non-classical photon pair generation and squeezed light is based on use of resonance devices, such as optical resonators, which result in increasing the efficiency of light matter interaction.

Optical whispering gallery mode resonators, ring and other optical resonators containing matter have been used to generate photon pairs through four-wave mixing (FWM) process resulting from the interaction of a laser's emission pumping a mode of the resonator with material possessing Kerr nonlinearity. This approach can be used in a cascaded process (cascaded FWM) whereby many harmonics of the frequency of pump lasers are generated in a so-called “frequency comb,” with corresponding pairs of harmonics on each side of the central mode that is pumped by the laser, produce photons that have nonclassical correlation. See, for example, Reimer et al., Cross-polarized photon-pair generation and bi-chromatically pumped optical parametric oscillation on a chip. Nat. Commun. 6, 8236 (2015).

A new approach is provided herein to significantly improve the efficiency of nonclassical photon pair generation by creating both classical and quantum correlation between the emission of lasers with their frequency injection locked to the pumping mode in a single resonator containing a Kerr nonlinearity. Employing two lasers that pump the same resonator at frequencies that are different (non-degenerate) influences the production of the comb with respect to stability of its operation. The two laser pumped nonlinear resonator also can produce novel types of the frequency combs.

Mixing two independent oscillators (e.g., lasers) can be used to generate a beat signal at the frequency difference of the two oscillators (e.g., lasers) characterized with noise equal to the sum of the noise of the two oscillators (e.g., lasers). For instance, if one creates a radio-frequency (RF) signal by beating two lasers on a photodiode, the phase noise of the generated signal should be equal to the sum of the noise of the lasers. This scheme can be used as a source of signals at frequencies set by the difference of frequencies of the two lasers. Synchronization of two oscillators (e.g., lasers) with unequal frequencies can result in reduction of relative oscillator noise in a certain frequency range. However, the relative noise typically cannot be better than the noise of a low frequency oscillator utilized in the scheme for synchronizing the two lasers.

A new approach is provided herein to further reduce the noise and/or to achieve other advantageous benefits.

### SUMMARY

In one aspect, a photonic device is provided that includes: an optical cavity with nonlinear optical characteristics; and a plurality of coherent optical sources, each configured to inject coherent light into an optical mode of the cavity at a different frequency to achieve self-injection locking of the optical source, with the nonlinear optical characteristics of the optical cavity configured to produce a plurality of corresponding frequency combs within the optical cavity, and with the each of the coherent optical sources optically injection locked to a pumped mode of the cavity; wherein the phase and amplitude of each of the coherent optical sources is set in combination with the nonlinear optical characteristics of the optical cavity to correlate the optical properties of the coherent light from the coherent optical sources.

In another aspect, a method is provided for use with a photonic device having an optical cavity with nonlinear optical characteristics. The method includes: generating a plurality of coherent optical beams using a plurality of coherent optical sources, each with a different frequency; injecting the plurality of optical beams into the optical cavity to self-injection lock each source, with the nonlinear optical characteristics of the optical cavity configured to produce a plurality of corresponding frequency combs within the optical cavity; and feeding back optical output from the optical cavity into each of the self-injection locked coherent optical sources to optically injection lock each of the coherent optical sources to a pumped mode of the cavity; wherein the phase and amplitude of each of the coherent optical sources is set in combination with the nonlinear optical characteristics of the optical cavity so that the optical properties of the coherent beams are correlated with one another.

In another aspect, an apparatus is provided that includes: an optical cavity with nonlinear optical characteristics; and a plurality of coherent optical sources, each configured to inject coherent light into the optical cavity at a different frequency and to receive feedback from the optical cavity to be phase locked; wherein the optical cavity and the plurality of coherent optical sources are configured to correlate the optical properties of the coherent light, and wherein the correlation is one or both of classical correlation and quantum correlation.

### BRIEF DESCRIPTION OF THE DRAWINGS

FIG. l illustrates an exemplary photonic system configured to provide quantum entangled output beams, in accordance with some aspects of the disclosure.

FIG. 2 illustrates two examples of self-injection locking.

FIG. 3 illustrates exemplary nonlinear wave mixing.

FIG. 4 illustrates to exemplary arrangements of photonic systems, one exploiting coherent backscattering and the other exploiting partial resonant reflection.

FIG. 5 is an exemplary photonic system that includes components configured to generate optical beams that are strongly correlated both in terms of classical and quantum correlation, including quantum entangled output beams.

FIG. 6 is a flow diagram illustrating a method for generating optical beams that are strongly correlated, including quantum entangled output beams.

FIG. 7 is a flow diagram illustrating a method for determining control parameters for a photonic system sufficient to generate optical beams that are strongly correlated, including quantum entangled output beams.

FIG. 8 illustrates another device configured in accordance with aspects of the disclosure.

FIG. 9 is a flow diagram illustrating another method in accordance with aspects of the disclosure.

FIG. 10 illustrates yet another device configured in accordance with aspects of the disclosure.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. In the figures, elements may each have a same reference number or a different reference number to suggest that the elements represented could be different and/or similar. However, an element may be flexible enough to have different implementations and work with some or all of the systems shown or described herein. The various elements shown in the figures may be the same or different and, which one is referred to as a first element and which is called a second element is arbitrary.

### Overview

Herein, it is disclosed that two or more lasers can be automatically quantum correlated in an optical system comprising lasers with nondegenerate (unequal) frequencies and a nonlinear optical cavity having at least a few optical modes belonging to the same mode family and with frequencies of several modes localized in the vicinity of both lasers emission frequencies. The correlation results from the generation of a single optical frequency comb spanning the frequency interval between the two lasers and having two harmonics coincident each with the frequencies of each laser; and with simultaneous optical coupling of the lasers and corresponding comb harmonics. As a result of the coupling, the light of the lasers will be quantum correlated.

Accordingly, a radio-frequency (RF) signal generated by the beat of the lasers on a fast photodiode will not depend on the intrinsic fundamental noise of each of the lasers and instead will be limited by the intrinsic noise of the frequency comb.

In this regard, the phase noise of a laser (same as the phase noise of any quantum oscillator) is limited due to the quantum nature of light. The ultimate linewidth of a laser is limited by the Schawlow-Townes linewidth. The Schawlow-Townes linewidth can also be explained in terms of Leeson formula developed for an oscillator of an arbitrary nature, showing that the power spectral density of phase noise of an oscillator has f⁻² fundamental frequency dependence, where f is the Fourier frequency.

As noted above, two independent oscillators (e.g., lasers) can be mixed to generate a beat signal at the frequency difference of the two oscillators characterized with noise equal to the sum of the noise of the two oscillators. For example, if one creates an RF signal by beating two lasers on a photodiode, the phase noise of the generated signal will be equal to the sum of the noise of the lasers. This scheme can be used as a source of signals at frequencies set by the difference of frequencies of the two lasers. Synchronization of two oscillators (e.g., lasers) with unequal frequencies can result in reduction of relative oscillator noise in a certain frequency range. However, the relative noise typically cannot be better than the noise of a low frequency oscillator if it is utilized in the scheme for synchronizing the two lasers.

The techniques introduced herein provide for both classical and quantum correlation of two or more lasers using the material nonlinearity of a nonlinear optical cavity. A nonlinear four-wave mixing process occurring in the cavity due to (or arising from) the Kerr nonlinearity of the cavity material can be utilized to introduce strong correlation among frequencies of the lasers as well as among the laser amplitudes. See, Reimer et al., cited above. See, also, Zhang et al., Spectral extension and synchronization of microcombs in a single microresonator. Nat. Commun. 11, 6384 (2020).

One of the possible wave mixing processes that results in the creation of correlation in the lasers is a cubic or Kerr nonlinearity. It is known that light from a continuous wave laser propagating in a resonator made with material possessing Kerr nonlinearity can produce a number of harmonics at frequencies corresponding to the free spectral range of the resonator, (i.e. a frequency comb). The comb is generated via cascaded four-wave mixing. In four-wave mixing two photons from the pump laser are annihilated to create two photons that form two harmonics symmetrically (with respect to frequency) about the pump frequency. The cascading of this process generates a comb, the details of which depends on the characteristics of the nonlinear material, the power of the laser and phase matching conditions. See, Kippenberg et al., Dissipative Kerr solitons in optical microresonators. Science 361, eaan8083 (2018).

When a nonlinear resonator (e.g., a nonlinear ring cavity or a whispering gallery mode resonator) is interrogated with polychromatic light from two or more lasers, the main role played by the nonlinear resonator is to mediate the formation of coherent harmonics (or correlating the light in the cavity modes in some other way). For example, if one couples the emission of two lasers into a nonlinear resonator, the resonant nonlinearity facilitates unitary (phase preserving) generation of optical harmonics with frequencies depending on both lasers. In a simple configuration (not shown) where there is no feedback from the resonator back into the lasers, the generation of the optical harmonics does not impact (act back upon) the lasers. However, if one injects the harmonics generated in the nonlinear resonator back into the lasers (as, for example, by self-injection locking of each laser to the same resonator), the lasers and the comb harmonics become correlated.

Note that various nonlinearity types (e.g., quadratic, Raman, ponderomotive, or high order) can be utilized to generate the frequency harmonics enabling the correlation of the lasers. The feedback to the lasers can be achieved both by selection of the properties of the cavity material and the external lumped elements (e.g., the lasers).

Turning now to quantum correlation, the above-described four-wave mixing in a cavity can produce optical harmonics that are quantum correlated. For instance, if one pumps a cavity with a single laser, the cavity generates a Kerr frequency comb that has harmonics symmetric with respect to the pump that are correlated in both photon number and frequency, i.e., quantum entangled. The photon numbers are correlated because of the photon number conservation law and the frequencies become correlated because of the energy and momentum conservation laws.

Assuming that the two quantum correlated harmonics generated in a nonlinear cavity are utilized for stabilization of two independent lasers, stabilization can take place by self-injection locking or similar schemes. The correlation allows creating two lasers with frequency noise below the Schawlow-Townes limit. Note that the powers of the lasers will not be correlated because the laser gains are free parameters.

The correlation can be further improved if there are two lasers generating frequency combs in a nonlinear resonator with each also interacting with the combs. Two lasers interacting with the same resonator can generally produce two independent combs, each as a result of their independent parameters of power, frequency and phase with the resonator material. (See, Zhang et al., cited above.) However, under certain conditions, the combs can be locked through Rayleigh scattering as well as general nonlinearity of the material. The complete locking of the combs occurs when the repetition rates of the combs (i.e., the pulse rates of corresponding time domain optical pulses or the frequency interval in the frequency domain) become identical due to nonlinearity of the material (the lasers introduce a nonlinear polarization of the material that locks the repetition rates) and the modes of the combs become locked due to the feedback of the comb harmonics to the lasers. If such an interaction occurs, the lasers producing the locked combs (thus forming a single comb produced simultaneously by both lasers) become correlated in phase and frequency and the relative quantum noise of the lasers becomes reduced. Importantly, the amplitudes of the lasers also become correlated. Indeed, the reduction of power of one of the lasers will result in increase of the power of the quantum feedback from the nonlinear frequency comb resulting in power increase. Since the amplification effect is of unitary nature, it leads to correlations of both the classical and quantum amplitude noise of the lasers.

As noted, a nonlinear cavity allows for reducing the absolute frequency noise of lasers below the quantum limit (squeezed light). Assuming that a mode locked comb produced by a pair of lasers has been formed in a nonlinear resonator, the power spectral density of phase noise of the repetition rate of the comb is L(f). The phase noise of the beat (n1-n2) of the two lasers pumping the comb is N²L(f), where N is the number of free spectral ranges (FSRs) separating the lasers. The phase noise of the other degree of freedom of the two lasers (n1+n2)/2 is approximately the same as the phase noise of a self-injection locked laser, L_{SIL}(f). Therefore, if the noise of the comb repetition rate is small, the improvement of the quantum noise for a single laser will be at least 3 dB if the lasers are perfectly locked together to keep jittering and drifting together in accordance with the self-injection locking.

A nonlinear cavity also allows reducing the phase noise of the signal generated by beating two lasers on a photodiode. Assuming that the lasers are mutually coherent according to the conditions described just above, the intracavity beat note power increases due to interference. This yields an improvement of phase noise of the beat note produced by the nonlinear comb on a fast photodetector by 6 dB (i.e., 4 times) when compared with a comb created by a single laser.

Thus, two or more lasers can become quantum correlated if their radiation is simultaneously coupled to a nonlinear cavity and then the output of the cavity is injected back to the lasers. Nonlinear interaction of two or more independent lasers with a nonlinear optical cavity results in the formation of an optical supermode that impresses quantum correlation on both frequency and amplitude of the lasers involved in the interaction. In the limiting case of the process, the nonlinear cavity-laser configuration generates discrete quantum locked states of mutually entangled optical fields.

### Exemplary Embodiments and Further Technical Details

FIG. 1 illustrates a system 100 with N lasers 102_{1 . . . N} and a nonlinear optical cavity 104. Each laser 102_{1 . . . N} sends a coherent optical beam 106_{1 . . . N} into the nonlinear optical cavity 104. A portion of the beam is fed back the nonlinear optical cavity 104 into the laser while another portion emerges from the nonlinear optical cavity 104 as an output beam 108_{1 . . . N}. Each of the lasers 102_{1 . . . N} have dissimilar (different) wavelengths. Given a particular nonlinear optical cavity and with proper selection of the phase and amplitude of each of the laser beams 106_{1 . . . N}, the nonlinear wave mixing process occurring within the nonlinear optical cavity 104 causes all of laser beams 106_{1 . . . N} and all of output beams 108_{1 . . . N} to be strongly correlated, both in terms of classical correlation and quantum correlation. That is, each of laser beams 106_{1 . . . N} becomes strongly correlated with each of the other laser beams 106_{1 . . . N}. Each of laser beams 106_{1 . . . N} also becomes strongly correlated with each of laser beams 108_{1 . . . N}. Each of the lasers 102_{1 . . . N} becomes strongly correlated with each of the other lasers 102_{1 . . . N}. In the example of FIG. 1, the correlation includes quantum correlation (in phase or number) so that the output beams provide a set of quantum entangled output beams 110. The lasers 102_{1 . . . N} and laser beams 106_{1 . . . N} are also quantum entangled.

In an ideal case, the above-described correlation results in complete suppression of the quantum f⁻² laser noise of the signal generated by mixing the lasers on a fast photodiode. Realistically and practically, noise can be suppressed to a degree defined by the nonlinear mixing process. Importantly, the nonlinear process allows for reducing the phase and frequency noise of the individual lasers below the fundamental Schawlow-Townes limit.

Thus, lasers 102_{1 . . . N} have dissimilar wavelengths and are used to pump the nonlinear optical cavity 104, which is capable of reflecting some part of light emitted by the lasers back to the lasers. Each of the lasers pumps a different mode of the cavity belonging to the same mode family. The optical back-reflection can result from Rayleigh scattering and/or artificial reflectors. In either case, the cavity is capable of mixing the laser frequencies and generating products of the mixing. The lasers can be made both classical and quantum correlated if the cavity is capable of producing a mixing frequency product in the vicinity of the eigenfrequency of each laser.

Exemplary processes are:
Pumping Laser 2 radiation into the cavity produces a frequency harmonic in the vicinity of frequencies of Laser 1, 3, . . . , N. By “vicinity,” it is meant that the eigenfrequency of the nonlinear harmonic is separated from the frequency of laser by a frequency detuning less than the Full Width at the Half Maximum (FWHM) of the corresponding cavity mode.
Pumping the cavity with Lasers 1 and 2 produces frequency harmonics at or near by frequencies of lasers 3, . . . . N.
Pumping the cavity with lasers 1, . . . N-1 produces a frequency harmonic at or near by of the eigenfrequency of Laser N.

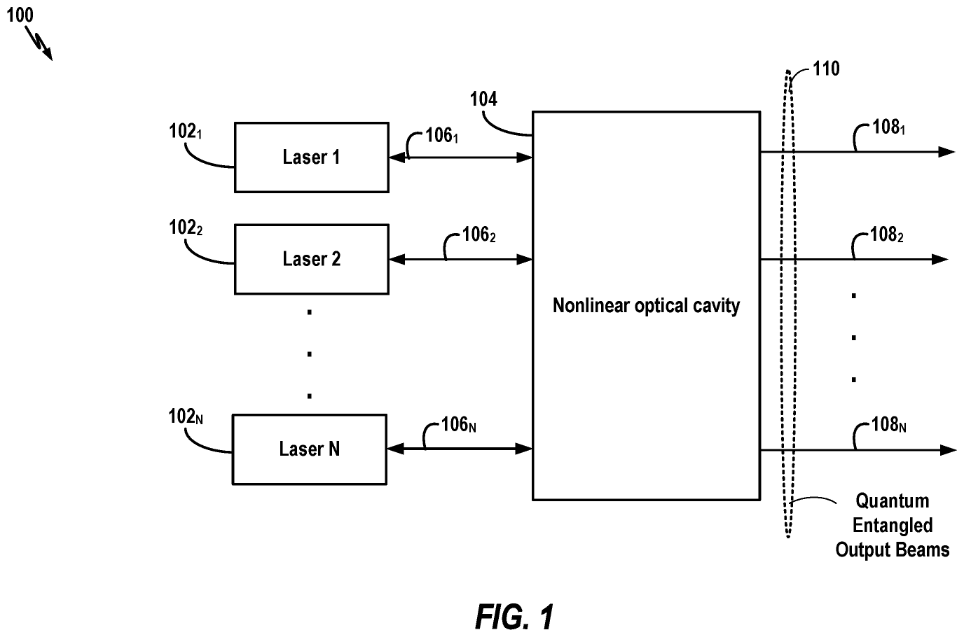

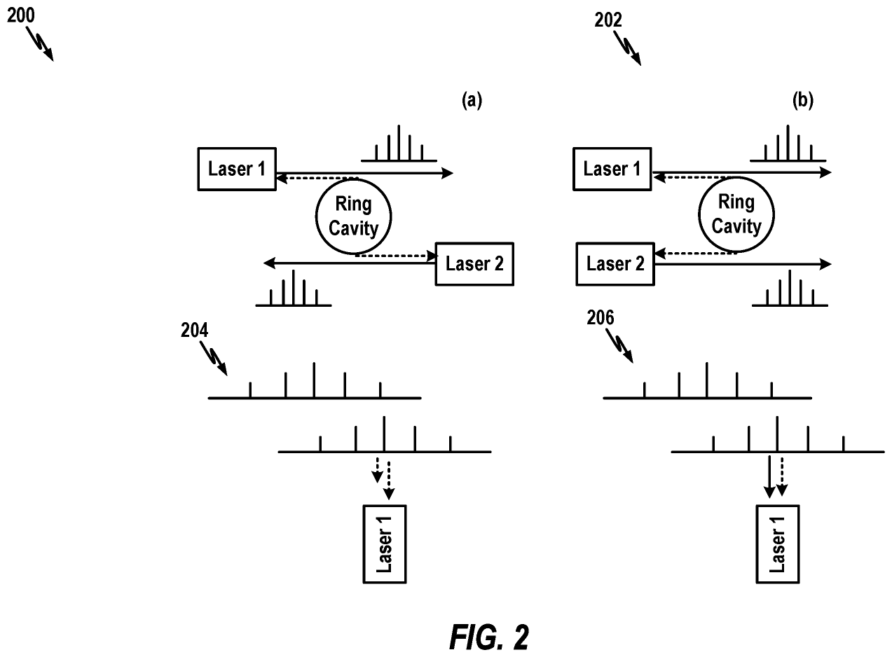

FIG. 2 illustrates two examples of self-injection locking: a first example 200 in which frequency combs are generated by co-propagating laser beams within a nonlinear ring cavity and a second example 202 in which frequency combs are generated within a nonlinear ring cavity from counter-propagating laser beams. In the first example, 200, a first laser (Laser 1) injects coherent light into a ring cavity to produce clockwise propagation of light within the ring. The nonlinear optical characteristics of the ring cavity result in a corresponding frequency comb (Comb 1) produced within the ring. A portion of the light of Comb 1 is back-scattered into Laser 1 by an amount sufficient to self-injection lock Laser 1. Concurrently, a second laser (Laser 2) injects light into the same ring cavity to generate additional clockwise propagating signals within the ring cavity. The light from Laser 2 produces another frequency comb (Comb 2) within the ring and a portion of the light of Comb 2 is back-scattered into Laser 2 by an amount sufficient to self-injection lock Laser 2. In this first example, 200, the combs propagating in the ring cavity are both clockwise and hence are co-propagating. If the phase and amplitude to the two lasers are both properly set, then at least one of the harmonics of one of the combs (e.g., Comb 1) will be fairly close in frequency with the peak of the other comb (e.g., Comb 2) as shown by graph 204.

In the second example, 202, of FIG. 2, the first laser (Laser 1) injects coherent light into a nonlinear ring cavity to produce clockwise propagation of light within the ring. The characteristics of the ring cavity again result in a corresponding frequency comb (Comb 1) produced within the ring. A portion of the light from Comb 1 is again back-scattered into Laser 1 by an amount sufficient to self-injection lock Laser 1. Concurrently, the second laser (Laser 2) injects light into the same ring cavity to generate counter-clockwise propagating signals within the ring cavity. The light from Laser 2 produces another frequency comb (Comb 2) and a portion of the light from Comb 2 is back-scattered into Laser 2 to self-injection lock Laser 2. In this second example, 202, the combs propagating in the ring cavity are counter-propagating. If the phase and amplitude to the two lasers are both properly set, then at least one of the harmonics of one of the combs (e.g., Comb 1) will be fairly close in frequency with the peak of the other comb (e.g., Comb 2) as shown by graph 206.

Note that in the first example, 200, at least some of the light from Laser 1 is also back-scattered into Laser 2 and some of the light from Laser 2 is also back-scattered into Laser 1 so that at least some of the light from each laser is fed into the other laser. Although this arrangement is not necessary to achieve correlation of the two lasers and their beams, the arrangement can help establish mutual locking. In the second example, 202, some of the light from Laser 1 is fed into Laser 2 (directly, not via back-scattering) and some of the light from Laser 2 is fed into Laser 1 (directly, not via back-scattering) so that at least some of the light from each laser is again fed into the other laser, which again serves to help establish locking.

In the co-propagating case of the first example, 200, the amount of light from Laser 1 that is back-scattered into Laser 2 and the amount of the light from Laser 2 that is back-scattered into Laser 1 is rather minimal. In the counter-propagating case of the second example, 202, the amount of light from Laser 1 that is fed into Laser 2 and the amount of the light from Laser 2 that is fed into Laser 1 is much greater. Hence, the counter-propagating arrangement of the second example, 202, can be more effective than the co-propagating arrangement of the first example, 200, in establishing locking. However, both arrangements can be used, as noted, to achieve correlation of the two lasers and their signals, it is not necessary to provide feedback from each laser into the other laser.

Thus, in the first example of FIG. 2, two lasers with near degenerate carrier frequencies excite copropagating light in a nonlinear ring resonator. Each of the lasers create its own frequency comb. Alternatively, the pair of laser creates a joint frequency comb. Optical feedback to the laser from the excited mode is much stronger than the feedback from the comb line. When the copropagating combs lock inside the resonator (creating, e.g., a time crystal), the feedbacks to the lasers become correlated in frequency. Therefore, in the co-propagating configuration the synchronization of the combs in the cavity results in the synchronization of the lasers.

In the second example of FIG. 2, the two lasers with near degenerate carrier frequencies excite counterpropagating frequency combs. The comb high order teeth injection to the lasers locking them together. The mechanism of locking can be stronger than the mechanism of locking of counter-propagating combs in a resonator. The repetition rates of the counter-propagating combs are usually locked through nonlinearity of the material (nonlinear polarization locking mechanism). The locking strength depends on the characteristic time of the comb indicating how fast excitation from one mode of the comb propagates to another mode.

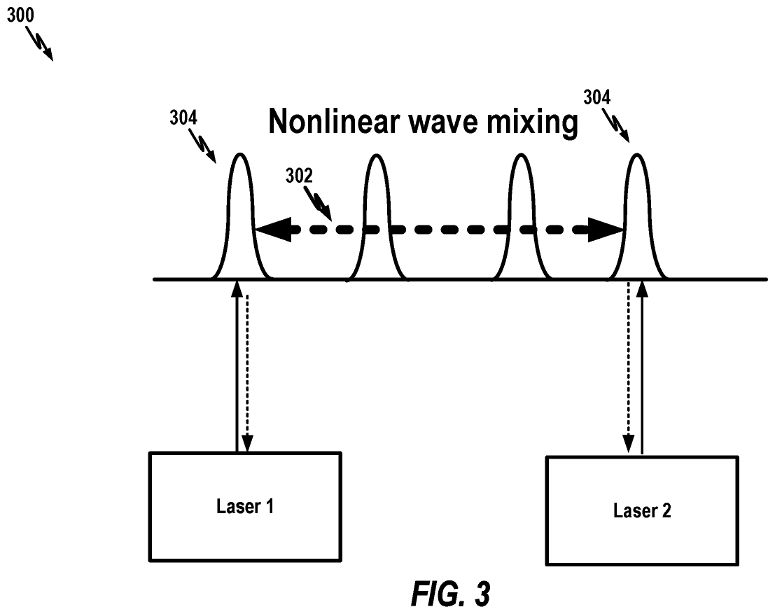

FIG. 3 illustrates the nonlinear wave mixing 300 that can occur between two lasers if their amplitudes and phases are properly set (in combination with the characteristics of the nonlinear resonator) to achieve the correlation described above. In FIG. 3, dashed arrow 302 represents the mixing that occurs between optical signals at different modes 304.

Correlation of noise of two lasers via a nonlinear optical cavity is established based on the operational principle of the laser noise correlator, which is based on the nonlinear optical cavity providing optical feedback to the lasers. Lasers 1 and 2 of FIG. 3 pump corresponding modes of the cavity. Some light reflects back from the cavity to the laser due to either linear or nonlinear coherent back scattering. The cavity modes are connected due to nonlinearity of the cavity through a nonlinear wave mixing process. In this configuration, the classical or/and quantum fluctuation of the lasers become correlated.

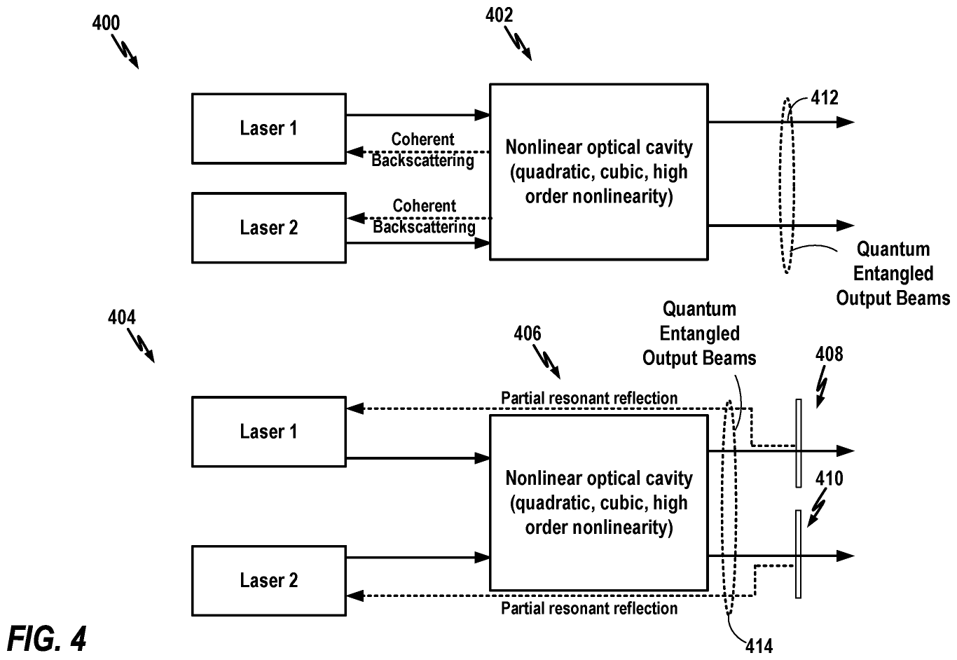

FIG. 4 illustrates two alternative arrangements. The first arrangement, 400, has first and second lasers (Laser 1 and Laser 2) coupled to a nonlinear optical cavity 402 that may be quadratic, cubic, ponderomotive, or provide a high order nonlinearity. As shown in the figure, coherent back-scattering is provided from the cavity 402 into both of the lasers. In a second arrangement, 404, the nonlinear optical cavity 406 can again be a quadratic, cubic, ponderomotive, or have a high order nonlinearity. In the example of 404, however, rather than exploiting back-scattering out of the cavity itself, a portion of the light of each beam is instead reflected back into the lasers from a corresponding reflecting component 408, 410, which could be, e.g., a half-silvered mirrors or any suitable reflecting surface or dispersive optical element that can provide optical feedback from the cavity to the lasers, such as a frequency independent optical delay line, an optically transparent material, or a dispersive element with frequency dependent attenuation. In both examples of FIG. 4, the correlation includes quantum correlation so the output beams provide a set of quantum entangled output beams. That is, the output beams 412 of cavity 402 are quantum entangled with one another. Also, the output beams 414 of cavity 406 are quantum entangled with one another. As with the system of FIG. 1, Laser 1 is also quantum correlated with Laser 2, and the optical beams propagated from and then back into the lasers are also quantum correlated.

### Exemplary Methods and Apparatus

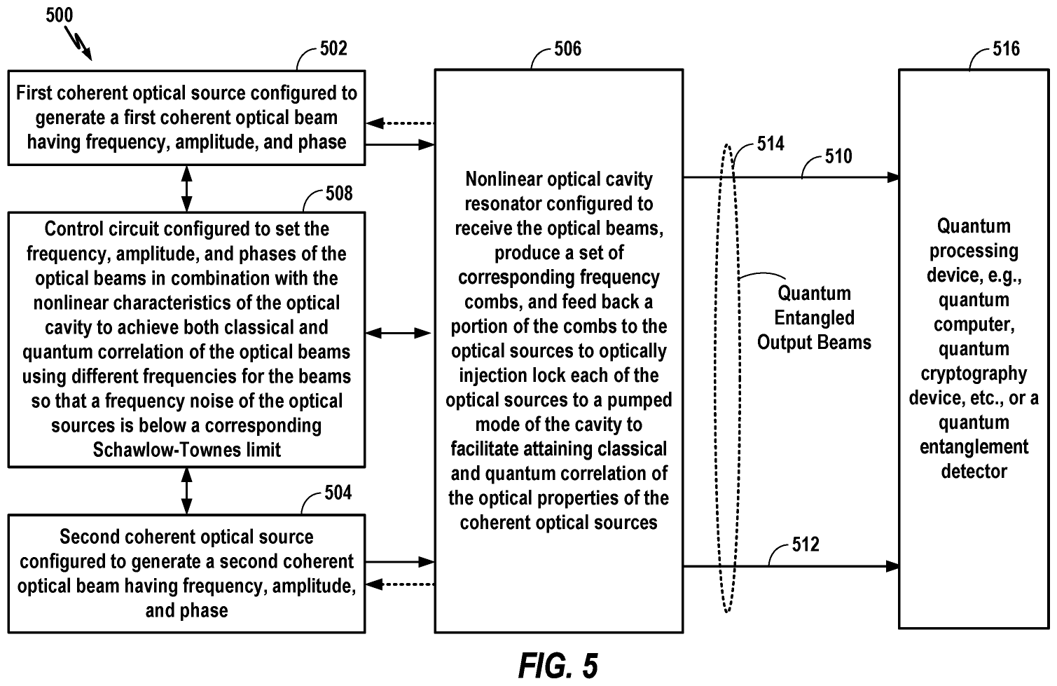

FIG. 5 is a block diagram of a photonic system, device or apparatus 500 that incudes components configured to generate optical beams that are strongly correlated both in terms of classical correlation and quantum correlation, including quantum entangled output beams. A first coherent optical source 502, such as a first semiconductor laser, is configured to generate a first coherent optical beam having frequency, amplitude, and phase. A second coherent optical source 504, such as a first semiconductor laser, is configured to generate a second coherent optical beam having frequency, amplitude, and phase. A nonlinear optical cavity resonator 506, such as a whispering gallery mode (WGM) resonator, is configured to receive the optical beams from sources 502 and 504, produce a set of corresponding frequency combs, and feedback a portion of the combs to the optical sources 502 and 504 (using broadband optical components shown by the dashed lines interconnecting the optical sources and the resonator) to lock both optical sources to a mode of its corresponding frequency comb to facilitate classical and quantum correlation of the optical properties of the coherent light sources 502 and 504. Alternatively, rather than feedback the optical signals directly from the cavity into the optical sources, the feedback can instead be achieved using elements that provide partial resonant reflection.

A control circuit 508 is configured to set the frequency, amplitude, and phases of the optical beams in combination with the nonlinear optical characteristics of the optical cavity to achieve both classical and quantum correlation of the optical beams using different frequencies for the beams so that a frequency noise of the optical sources is below a corresponding Schawlow-Townes limit. As a result, a pair of output beams 510 and 512 are quantum entangled, 514. The coherent optical sources 502 and 504 are also quantum entangled, as well as the beams that optical beams propagated between the sources optical and the resonator. In the example of FIG. 5, the entangled output beams 510, 512 are applied to a quantum processing device 516 configured to exploit the entangled beams, such as a quantum computing device or a quantum cryptography device for secure communications. Other quantum devices can include quantum sensors or quantum simulators. The quantum processing device 516 can also be a quantum entanglement detector configured to detect quantum entangled beams to confirm the entanglement. Applications also include low noise oscillators, when the light of the two lasers are combined on a fast photodetector.

Note that in the example of FIG. 5, the control circuit 508 can control both of the optical sources 502 and 504 as well as the nonlinear resonator 506. For example, the nonlinear resonator 506 may be configured so that its resonant characteristics (or parameters e.g., the frequencies at which it generates backscatter) may be controlled by varying its temperature or by applying mechanical pressure or electric currents, etc. In this manner, the characteristics of the frequency combs produced within the resonator can be adjusted by the control circuit along with the parameters of the optical sources. For example, the optical sources can be made both classical and quantum correlated by controlling the various parameters of the optical sources and the cavity so that the cavity produces a mixing frequency product in the vicinity of the eigenfrequency of each optical sources, where “vicinity” was defined above (i.e., the eigenfrequency of the nonlinear harmonic is separated from the frequency of the coherent optical source by a frequency detuning less than the FWHM of the corresponding cavity mode.

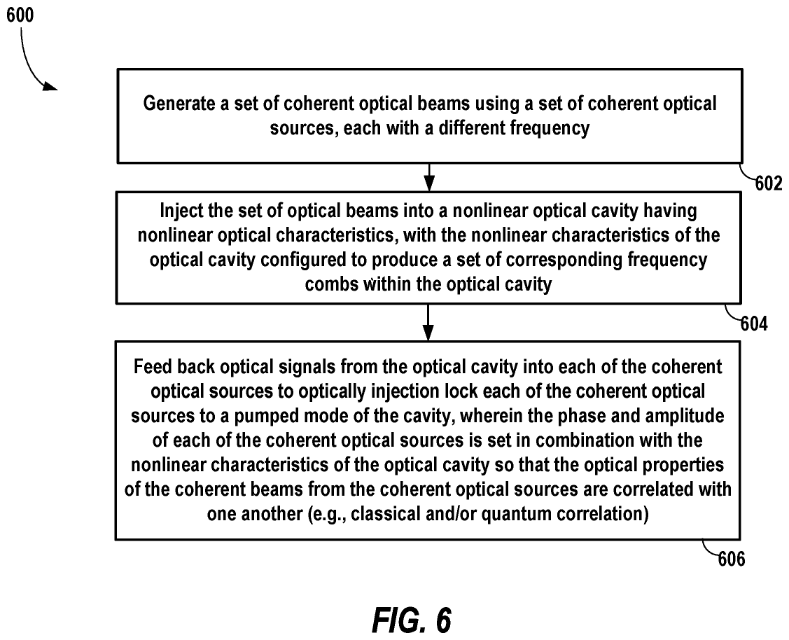

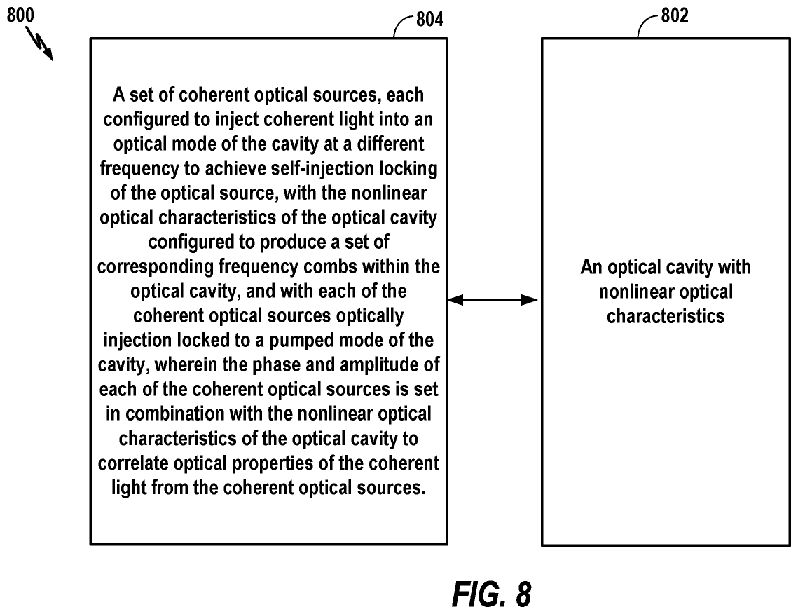

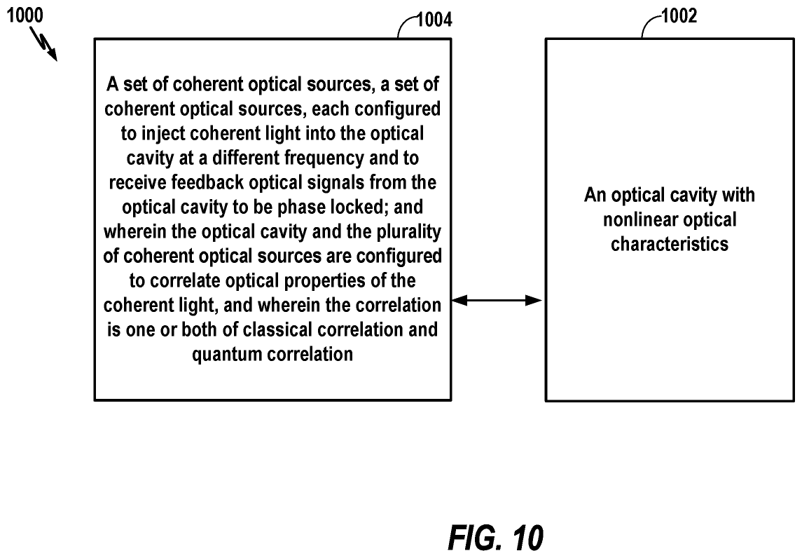

FIG. 6 illustrates a method 600 that may be performed by the photonic systems of FIGS. 1, 2, 3, 4, or 5 (or FIGS. 8 or 10, discussed below) or by other suitably-equipped systems, devices, or apparatus. Briefly, at block 602, the method includes generating a set or plurality of coherent optical beams using a set or plurality of coherent optical sources (such as semiconductor lasers), each with a different frequency. At block 604, the method includes injecting the plurality of optical beams into the optical cavity, with the nonlinear optical characteristics of the optical cavity configured to produce a set or plurality of corresponding frequency combs within the optical cavity. At block 606, the method includes feeding back optical signals from the optical cavity into each of the coherent optical sources to optically injection lock each of the coherent optical sources to a pumped mode of the cavity, wherein the phase and amplitude of each of the coherent optical sources is set in combination with the nonlinear optical characteristics of the optical cavity so that the optical properties of the coherent beams from the coherent optical sources are correlated with one another. As explained above, the optical sources can be made both classical and quantum correlated by controlling the various parameters of the optical sources and the cavity so that the cavity produces a mixing frequency product in the vicinity of the eigenfrequency of each optical sources. Alternatively, rather than feedback the optical signals directly from the cavity into the optical sources, the feedback can instead be achieved using dispersive elements that provide partial resonant reflection.

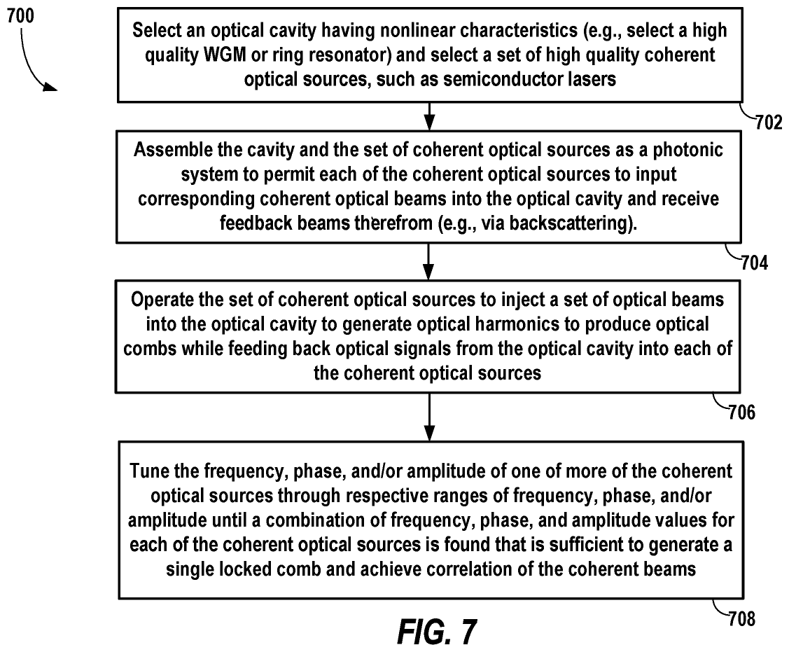

FIG. 7 illustrates a method 700 that may be performed in conjunction with the photonic systems of FIGS. 1, 2, 3, 4, or 5 (or FIGS. 8 or 10, discussed below) or by other suitably-equipped systems, devices, or apparatus. Briefly, at block 702, the method includes selecting an optical cavity having nonlinear optical characteristics (e.g., select a high quality WGM or ring resonator), and then selecting a set of high quality coherent optical sources, such as semiconductor lasers. At block 704, the method includes assembling the cavity and the set of coherent optical sources as a photonic system to permit each of the coherent optical sources to input corresponding coherent optical beams into the optical cavity and receive feedback beams therefrom (e.g., via backscattering). Alternatively, the photonic system can be configured to provide feedback using dispersive elements that provide partial resonant reflection. At block 706, the method includes operating the set of coherent optical sources to inject a set or plurality of optical beams into the optical cavity to generate optical harmonics to produce optical combs while feeding back optical signals from the optical cavity (or via dispersive elements) into each of the coherent optical sources. At block 708, the method includes tuning the frequency, phase, and/or amplitude of one of more of the coherent optical sources through respective ranges of frequency, phase, and/or amplitude until a combination of frequency, phase, and amplitude values for each of the coherent optical sources is found that is sufficient to generate a single locked comb and achieve correlation of the coherent beams. For a particular photonic system, the particular combination of parameters which achieves the correlation may be detected by applying output signals from the optical cavity of the system to a quantum entanglement detector capable of detecting entangled beams.

FIG. 8 summarizes aspects of a device 800 configured in accordance with aspects of the disclosure. The device 800 includes an optical cavity 802 with nonlinear optical characteristics. The device 800 also includes set (or plurality) of coherent optical sources 804, each configured to inject coherent light into an optical mode of the cavity at a different frequency to achieve self-injection locking of the optical source, with the nonlinear optical characteristics of the optical cavity configured to produce a set (or plurality) of corresponding frequency combs within the optical cavity, and with each of the coherent optical sources optically injection locked to a pumped mode of the cavity, wherein the phase and amplitude of each of the coherent optical sources is set in combination with the nonlinear optical characteristics of the optical cavity to correlate optical properties of the coherent light from the coherent optical sources.

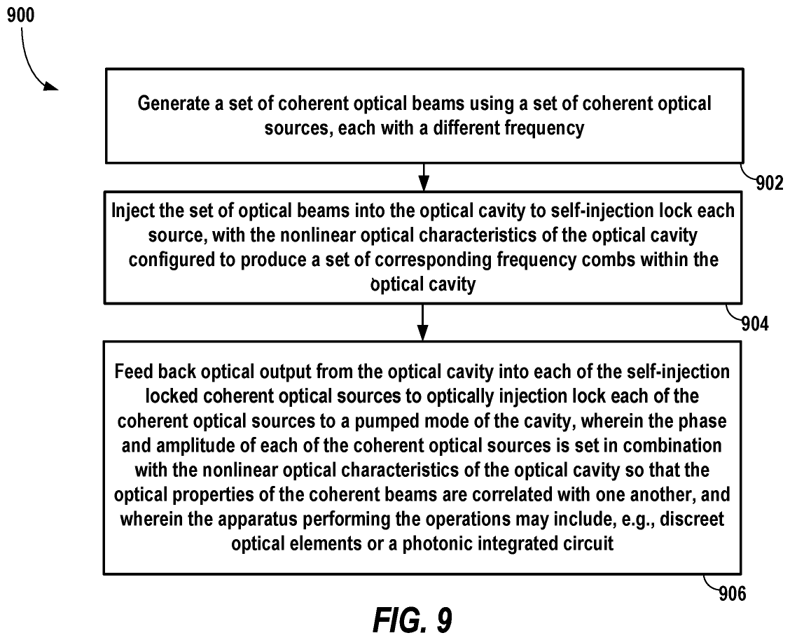

FIG. 9 summarizes aspects of a method 900 for use with a photonic device having an optical cavity with nonlinear optical characteristics that may be performed in conjunction with the photonic systems of FIGS. 1, 2, 3, 4, 5, or 8 (or FIG. 10, discussed below) or by other suitably-equipped systems, devices, or apparatus. At block 902, the method includes generating a plurality of coherent optical beams using a plurality of coherent optical sources, each with a different frequency. At block 904, the method includes injecting the plurality of optical beams into the optical cavity to self-injection lock each source, with the nonlinear optical characteristics of the optical cavity configured to produce a plurality of corresponding frequency combs within the optical cavity. At block 906, the method includes feeding back optical output from the optical cavity into each of the self-injection locked coherent optical sources to optically injection lock each of the coherent optical sources to a pumped mode of the cavity, wherein the phase and amplitude of each of the coherent optical sources is set in combination with the nonlinear optical characteristics of the optical cavity so that the optical properties of the coherent beams are correlated with one another, and wherein the apparatus performing the operations may include, e.g., discreet optical elements or a photonic integrated circuit.

FIG. 10 summarizes aspects of a device 1000 configured in accordance with aspects of the disclosure. The device 1000 includes an optical cavity 1002 with nonlinear optical characteristics. The device 1000 also includes set (or plurality) of coherent optical sources 1004, each configured to inject coherent light into the optical cavity at a different frequency and to receive feedback optical signals from the optical cavity to be phase locked; wherein the optical cavity and the plurality of coherent optical sources are configured to correlate optical properties of the coherent light, and wherein the correlation is one or both of classical correlation and quantum correlation (i.e., classical correlation and/or quantum correlation).

Note that the devices shown and described herein may be implemented with one or more discreet optical elements or as a photonic integrated circuit (or one or more photonic integrated circuits). Likewise, the methods shown and described herein may be performed using one or more discreet optical elements or using a photonic integrated circuit (or one or more photonic integrated circuits).

### Additional Aspects and Considerations

Note that one or more of the components, steps, features, and/or functions illustrated in FIGS. 1, 2, 3, 4, 5, 6, 7, 8, 9, and/or 10 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, an aspect is an implementation or example. Reference in the specification to “an aspect,” “one aspect,” “some aspects,” “various aspects,” or “other aspects” means that a particular feature, structure, or characteristic described in connection with the aspects is included in at least some aspects, but not necessarily all aspects, of the present techniques. The various appearances of “an aspect,” “one aspect,” or “some aspects” are not necessarily all referring to the same aspects. Elements or aspects from an aspect can be combined with elements or aspects of another aspect.

The term “coupled” may mean that two or more elements are in direct physical or electrical contact. However, “coupled” may also mean that two or more elements are not in direct contact with each other, but yet still co-operate or interact with each other.

Not all components, features, structures, characteristics, etc. described and illustrated herein need be included in a particular aspect or aspects. If the specification states a component, feature, structure, or characteristic “may,” “might,” “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although some aspects have been described in reference to particular implementations, other implementations are possible. Additionally, the arrangement and/or order of elements or other features illustrated in the drawings and/or described herein need not be arranged in the particular way illustrated and described. Many other arrangements are possible according to some aspects.

Also, it is noted that the aspects of the present disclosure may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A photonic device, comprising:
an optical cavity with nonlinear optical characteristics; and
a plurality of coherent optical sources, each configured to inject coherent light into an optical mode of the cavity at a different frequency to achieve self-injection locking of the optical source, with the nonlinear optical characteristics of the optical cavity configured to produce a plurality of corresponding frequency combs within the optical cavity, and with each of the coherent optical sources optically injection locked to a pumped mode of the cavity; and
wherein the phase and amplitude of each of the coherent optical sources is set in combination with the nonlinear optical characteristics of the optical cavity to correlate optical properties of the coherent light from the coherent optical sources.

2. The photonic device of claim 1, wherein the phase and amplitude of each of the coherent optical sources is set in combination with the nonlinear optical characteristics of the optical cavity and the lock to the cavity modes to achieve one or both of classical correlation and quantum correlation of the optical properties of the coherent light from the coherent optical sources.

3. The photonic device of claim 1, wherein the coherent optical sources are semiconductor lasers.

4. The photonic device of claim 1, wherein the optical cavity is a resonator.

5. The photonic device of claim 1, wherein the optical cavity is a whispering gallery mode cavity.

6. The photonic device of claim 1, further comprising components configured to inject output optical signals from the optical cavity back into the plurality of coherent optical sources to self-injection lock the coherent optical sources.

7. The photonic device of claim 6, wherein the components configured to inject output optical signals back into the coherent optical sources comprise broadband optical components.

8. The photonic device of claim 6, wherein the optical cavity is configured to provide resonant Rayleigh back reflection to provide optical feedback from the optical cavity into the plurality of coherent optical sources to lock the coherent optical sources via self-injection locking.

9. The photonic device of claim 6, further comprising an optical element configured and positioned to provide reflected optical feedback from the optical cavity to the plurality of coherent optical sources to lock the coherent optical sources via self-injection locking.

10. The photonic device of claim 9, wherein the optical element introducing optical feedback into the cavity comprises one or more of a frequency independent optical delay line, an optically transparent material, a dispersive element with frequency dependent attenuation, or a reflecting surface.

11. The photonic device of claim 1, further configured to output a plurality of coherent optical signals from the optical cavity for output from the photonic device.

12. The photonic device of claim 1, further comprising a photodiode configured to receive a plurality of coherent optical signals from the optical cavity and generate a radio-frequency (RF) signal, with the RF signal derived from a beat signal generated by frequency differences in the plurality of coherent optical signals.

13. The photonic device of claim 1, wherein a frequency noise of each of the plurality of coherent optical sources is below a corresponding Schawlow-Townes limit.

14. The photonic device of claim 1, wherein the correlation of the optical properties of the coherent light from the coherent optical sources comprises a correlation in one or more of frequency and amplitude.

15. The photonic device of claim 1, wherein the correlation of the optical properties of the coherent light from the coherent optical sources comprises a correlation in one or more of classical noise and quantum noise.

16. The photonic device of claim 1, wherein the correlation of the optical properties of the coherent light from the coherent optical sources comprises one or more discrete quantum locked states of mutually entangled optical fields.

17. The photonic device of claim 1, wherein the phase and amplitude of each of the coherent optical sources is set in combination with the nonlinear optical characteristics of the optical cavity to produce a mixing frequency product in the vicinity of an eigenfrequency of each coherent optical source, wherein vicinity is defined as the eigenfrequency of a nonlinear harmonic being separated from the frequency of a corresponding coherent optical source by a frequency detuning that is less than a Full Width at the Half Maximum of a corresponding cavity mode.

18. A method for use with a photonic device having an optical cavity with nonlinear optical characteristics, the method comprising:
generating a plurality of coherent optical beams using a plurality of coherent optical sources, each with a different frequency;
injecting the plurality of optical beams into the optical cavity to self-injection lock each source, with the nonlinear optical characteristics of the optical cavity configured to produce a plurality of corresponding frequency combs within the optical cavity; and
feeding back optical output from the optical cavity into each of the self-injection locked coherent optical sources to optically injection lock each of the coherent optical sources to a pumped mode of the cavity; and
wherein the phase and amplitude of each of the coherent optical sources is set in combination with the nonlinear optical characteristics of the optical cavity so that the optical properties of the coherent beams are correlated with one another.

19. The method of claim 18, wherein the phase and amplitude of each of the coherent optical sources are set in combination with the nonlinear optical characteristics of the optical cavity by:
selecting a particular optical cavity having nonlinear optical characteristics;
injecting the plurality of coherent beams into the optical cavity while feeding optical signals from the optical cavity into each of the coherent optical sources; and
tuning the frequency, phase, and/or amplitude of one of more of the coherent optical sources through respective ranges of frequency, phase, and/or amplitude until a combination of frequency, phase, and amplitude values for each of the coherent optical sources is found that is sufficient to achieve the correlation of the coherent beams.

20. An apparatus, comprising:
an optical cavity with nonlinear optical characteristics;
a plurality of coherent optical sources, each configured to inject coherent light into the optical cavity at a different frequency and to receive feedback optical signals from the optical cavity to be phase locked; and
wherein the optical cavity and the plurality of coherent optical sources are configured to correlate optical properties of the coherent light, and wherein the correlation is one or both of classical correlation and quantum correlation.
